(19) United States
(12) Patent Application Publication
(10) Pub. No.: US 2007/0066097 A1
(43) Pub. Date: Mar. 22, 2007

(54) Fuse connnection box

(75) Inventor: Eiji Higuchi, Yokkaichi-city (JP)

Correspondence Address: OLIFF & BERRIDGE, PLC, P.O. BOX 19928, ALEXANDRIA, VA, 22320, US

(73) Assignee: SUMITOMO WIRING SYSTEMS, LTD., Yokkaichi-city (JP)

(21) Appl. No.: 11/509,646

(22) Filed: Aug. 25, 2006

(30) Foreign Application Priority Data
Sep. 2, 2005 (JP) 2005-254899

(51) Int. Cl. H05K 1/00

(52) U.S. Cl. 439/76.2

(57) ABSTRACT

In a fuse connection box, a pair of terminal fittings is inserted through one end of a housing and a fuse is inserted from the other end of the housing to connect input and output terminals of the fuse with a pair of the terminal fittings. The housing includes a pair of partitioning walls spaced from each other at a certain interval. A pair of terminal accommodation chambers are surrounded by the partitioning walls and a peripheral wall of the housing. A pair of lances, to be locked to locking portions of the terminal fittings, is provided at distal ends of a pair of the partitioning walls. A reinforcing connection frame connects a pair of the partitioning walls to each other, and may strengthen the partitioning walls against deformation and/or help reduce entry of water into the housing. A flexing restraining rib projects from an upper surface of the reinforcing connection frame, to prevent excessive deformation of the frame.

This application claims priority from Japanese Patent Application 2005-254899, filed Sep. 2, 2005, the entire contents of which are incorporated herein by reference.

### BACKGROUND

The present invention relates to a fuse connection box. A fuse may be removably inserted from one side of the fuse connection box and terminal fittings connected to ends of electric wires disposed in a car body may be inserted from the other side of the fuse connection box to connect the terminal fittings and input and output terminals of the fuse to each other. The fuse connection box is preferably used to accommodate a fuse which has a small height and approximately a quadrangular shape. Input and output terminals of the fuse connection box are exposed from cut-outs disposed at left and right sides of a fuse body made of resin.

A fuse connection box of this kind is proposed and disclosed in Japanese Patent Application Laid-Open No. 2004-158256 (JP-A-2004-158256). As shown in FIGS. 6 and 7, a pair of female terminals 3 crimped to the ends of a pair of electric wires W is inserted into a pair of the terminal accommodation chambers 2 of the fuse connection box 1 from openings formed at one end of the fuse connection box 1. Locking portions 4a provided at the free-end side of a pair of the lances 4 projected inside the terminal accommodation chamber 2 or locked to locking stepped portions 3a formed on the female terminals 3. The space communicating with the distal side of the terminal accommodation chambers 2 of the fuse connection box 1 is formed as a fuse accommodation chamber 5. A fuse 6 is removably inserted into the fuse accommodation chamber 5. Thereby the input terminal 6a and the output terminal 6b of the fuse 6 and the terminals 3 are connected with each other by fitting the terminals 6a, 6b and the terminals 3 to each other.

When the terminals are removed from the fuse connection box 1, an unlocking jig (not shown) is inserted into the fuse connection box 1 from the free end side of the lances 4 to unlock the locking stepped portions 3a from the locking portions 4a by flexing the locking portions 4a. To prevent the lances 4 from flexing excessively, a contact member 7 is mounted between the lances 4.

### SUMMARY

As shown in FIG. 7B, in the construction disclosed in JP-A-2004-158256, both ends of the contact member 7 are fixed to a partitioning wall 8. Thus when a force is applied to the central portion of the contact member 7, the contact member 7 deforms in the shape of a bow which may allow the lances to flex excessively and possibly break. Further, because the contact member 7 is mounted in the penetration space of the opening of the fuse connection box 1 between the lances 4, water may be able to penetrate into the fuse connection box 1 from the lower end opening of the fuse connection box 1. If water penetrates into the fuse connection box 1, the water may moisten the fuse 6 and/or the terminals 3. Thus, the construction disclosed in JP-A-2004-158256 may exhibit poor waterproof performance.

The present invention has been made in view of the above-described problem. Accordingly, it is an object of exemplary embodiments of the present invention to provide a fuse connection box having an improved mechanism for preventing a pair of lances from excessively elastically deforming when terminal fittings connected to ends of a pair of electric wires are unlocked from the lances to prevent the lances from being broken. It is another object of exemplary embodiments of the present invention to provide a fuse connection box having improved waterproof performance.

To achieve these objects, embodiments of the present invention provide a fuse connection box in which a pair of terminal fittings connected to ends of a pair of electric wires is inserted into a terminal accommodation space from a terminal insertion opening disposed at one end of a connection housing, and a fuse is inserted into a fuse accommodation space from a fuse insertion opening at the other end of the connection housing and mounted in the fuse accommodation space to connect input and output terminals of the fuse with a pair of the terminal fittings respectively mounted on the ends of the electric wires.

The housing of the fuse connection box includes a pair of partitioning walls disposed upward from the terminal insertion opening inside the terminal accommodation space, with the partitioning walls spaced from each other at a certain interval; a pair of terminal accommodation chambers surrounded by the partitioning walls and a peripheral wall of the housing; a pair of lances, to be locked to locking portions of the terminal fittings, which is provided at distal ends of a pair of the partitioning walls; a reinforcing connection frame connecting the pair of partitioning walls to each other; and a flexing restraining rib projected from an upper surface of the reinforcing connection frame.

In the above-described construction, when the lances are flexed by the unlocking jig inserted into the fuse accommodation space to unlock the terminals from the lances respectively, the lances may be prevented from being excessively flexed. This is because the lances are formed at the distal ends of a pair of the partitioning walls and because the opposed partitioning walls are connected to each other with the reinforcing “H”-shaped connection frame. Further, the flexing restraining rib projects from the reinforcing connection frame. When the lances flex beyond a certain extent, the lances contact the flexing restraining rib, which prevents the lances from being excessively flexed. Because the flexing restraining rib is firm and projects from the upper surface of the reinforcing connection frame, the flexing restraining rib is prevented from being deformed by the elastically deformed lances. Further, the integration of the lances with the partitioning wall contributes to miniaturization of the fuse connection box.

The reinforcing connection frame connecting the pair of partitioning walls to each other may serve as a waterproof wall.

In the above-described construction, the reinforcing connection frame shuts out water which has penetrated into the fuse connection box from the opening formed through the lower end of the housing between the partitioning walls, thereby preventing the water from wetting the fuse or the terminals, and thereby enhancing the waterproof performance of the fuse connection box.

The reinforcing connection frame may be spaced at a certain interval from proximal positions of the pair of lances. The flexing restraining rib projects from a central portion of the reinforcing connection frame, with a gap formed between the flexing restraining rib and the lances disposed at both sides of the flexing restraining rib.

In the above-described construction, the reinforcing connection frame is spaced at a required dimension from the proximal end of the lances. Thus, in unlocking the terminal from the lances with the unlocking jig, the lances flex only to such an extent that the lances are capable of returning to their original state. Further, the elastic deformation of the lances does not affect the position where the reinforcing connection frame is formed. Consequently it is possible to relieve a stress generated at a boundary between the reinforcing connection frame and the partitioning walls and reliably prevent breakage of the lances disposed at the distal sides of the partitioning walls.

If the flexing restraining rib is rod-shaped, a sufficient space is provided between the lances and the flexing restraining rib to allow the lance to flex in the space.

The reinforcing connection frame is disposed in the vicinity of proximal positions of the pair of lances. The flexing restraining rib may be sectionally mountain-shaped and project from the central portion of the reinforcing connection frame, with a gap between the flexing restraining rib and the lances gradually increasing toward the free ends of the lances.

In the above-described construction, when the flexing restraining rib contacts the lances, the elastically deformed lances make a surface contact with the inclined surface of the flexing restraining rib and are held thereby because the flexing restraining rib is mountain-shaped. Therefore the stress caused by flexing the lances should not concentrate on one point of the lances which may reduce the possibility of breaking the lances.

Instead of the mountain-shaped flexing restraining rib, the rod-shaped flexing restraining rib may be projected from the central portion of the reinforcing connection frame.

The fuse to be accommodated in the fuse accommodation space has an input terminal and an output terminal parallel therewith, both exposed from cut-outs disposed at left and right sides of the rectangular fuse body. The height of the fuse accommodation space is so set that the fuse body can be fitted therein.

Because the input terminal and the output terminal are not longitudinally projected from the fuse body, the height of the fuse can be made smaller than a fuse in which the terminals longitudinally project from the fuse body. Consequently, the fuse connection box can be made compact and lightweight.

As apparent from the foregoing description, in the fuse connection box of embodiments of the present invention, during disconnection of the terminals connected with of the electric wires from the fuse connection box, the lances are flexed by the unlocking jig inserted into the fuse accommodation space to unlock the terminals from the lances. In this unlocking operation, the lances may be less likely to be excessively flexed and/or broken because the lances are formed at the distal end of the partitioning walls, which are connected to each other with the reinforcing connection frame. In addition, the flexed lances may contact the flexing restraining rib projecting from the reinforcing connection frame, which may also reduce the possibility of the lances being excessively flexed.

The partitioning walls may be connected with each other by the reinforcing connection frame to form a waterproof wall therebetween. The reinforcing connection frame shuts out water which has penetrated into the fuse connection box through the opening formed in the lower peripheral wall of the housing between the partitioning walls, thereby preventing the water from wetting the fuse and the terminals. This helps reduce the possibility of corrosion.

These and other objects, advantages and features are described in and apparent from the following detailed description.

### BRIEF DESCRIPTION OF THE DRAWINGS

Exemplary embodiments will be described in connection with the attached drawings, in which like numerals represent like ports, and which:

FIG. 1 is a sectional view showing a fuse connection box of a first embodiment of the present invention;

FIG. 2 is a main part-enlarged sectional view seen in a direction shown with an arrow (from the left side) of FIG. 1;

FIG. 3 is a sectional view showing a state in which a fuse and terminal fittings connected to ends of electric wires are inserted into the fuse connection box of the first embodiment to connect the fuse and the terminal fittings to each other;

FIG. 4 is a sectional view showing an operation of unlocking terminal fittings connected to the ends of electric wires from lances provided inside the fuse connection box;

FIG. 5 is a sectional view showing a fuse connection box of a second embodiment of the present invention;

FIG. 6 is a perspective view showing a conventional fuse box;

FIG. 7A is a sectional view showing the conventional fuse box shown in FIG. 6; and

FIG. 7B is a bottom view showing the conventional fuse box shown in FIG. 6.

### DETAILED DESCRIPTION OF EMBODIMENTS

Exemplary embodiments of the present invention will be described below with reference to drawings.

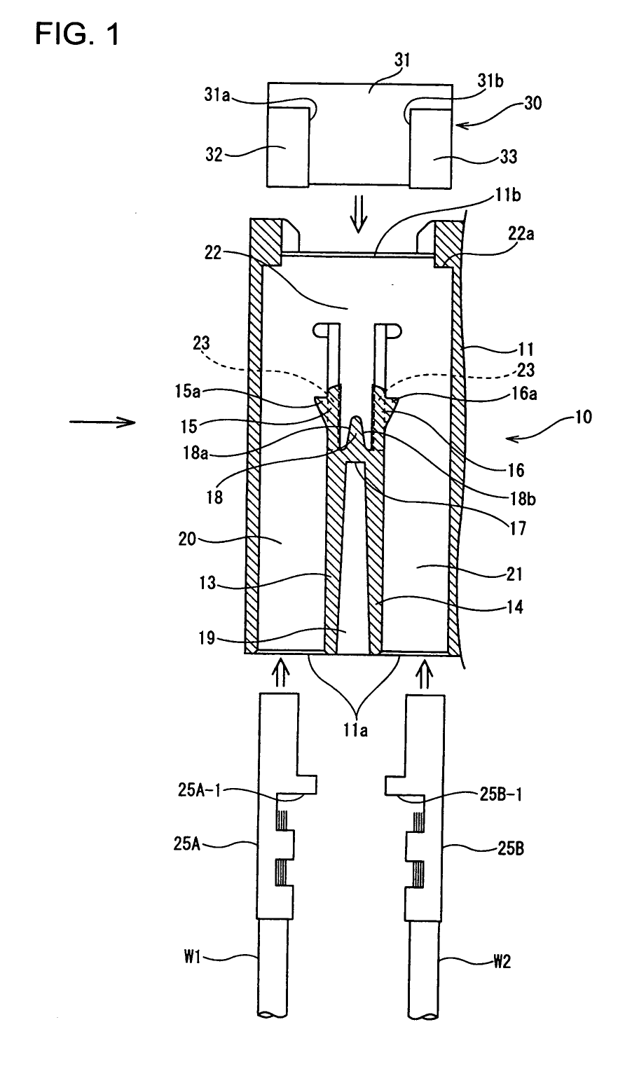

FIGS. 1 through 4 show a first embodiment of the present invention.

As shown in FIG. 1, a fuse connection box 10 has a function of connecting a fuse 30 and a pair of electric wires W (W1, W2) to each other. An opening at one end of a housing 11 is formed as a terminal fitting insertion opening 11a for a pair of terminal fittings (hereinafter referred to as terminals) crimped to ends of the electric wires W1, W2 respectively. Another opening is formed at the other end of the housing 11 as a fuse insertion opening 11b.

Inside the housing 11, a terminal accommodation space at the side of the terminal fitting insertion opening 11a is partitioned with a pair of partitioning walls 13, 14 to form a pair of terminal accommodation chambers 20, 21. Inside the housing 11, a space at the side of the fuse insertion opening 11b is formed as a fuse accommodation space 22 communicating with a pair of the terminal accommodation chambers 20, 21.

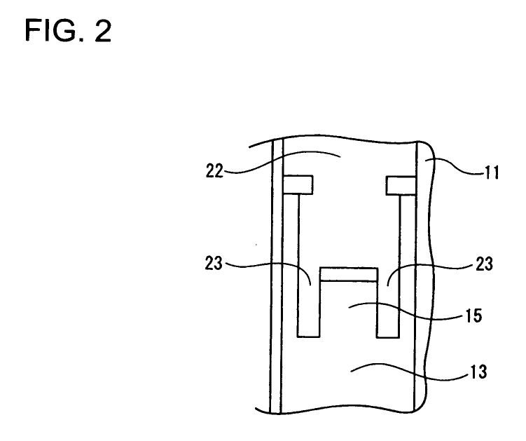

As shown in FIG. 2, two slits 23 are formed in the partitioning walls 13 and 14 from approximately a vertically central position thereof toward the fuse insertion opening 11b to form elastically deformable lances 15, 16. Locking claws 15a, 16a are projected from the lances 15, 16 respectively toward the terminal accommodation chambers 20, 21. The partitioning walls 13, 14 are connected to each other with an “H”-shaped reinforcing connection frame 17 in the vicinity of proximal positions (proximal position of slit 23) of the lances 15, 16. Each of the lances 15, 16 is capable of elastically deforming, with a free end disposed at the side where the locking claws 15a, 16a are formed and with a fixed end disposed at the proximal side of the slit 23.

A penetration space 19 communicating with the terminal fitting insertion opening 11a is formed between the partitioning walls 13 and 14. The reinforcing connection frame 17 shields the penetration space 19, thereby functioning as a waterproof wall.

A flexing restraining rib 18, sectionally mountain-shaped, projects from an upper surface of the central portion of the reinforcing connection frame 17. The flexing restraining rib 18 is lower than the upper end of the locking claws 15a, 16a of the lances 15, 16 disposed at both sides of the flexing restraining rib 18. The gap between the lance 15 and an inclined surface 18a of the flexing restraining rib 18 and the gap between the lance 16 and an inclined surface 18b are gradually increased toward the free ends of the lances 15, 16.

Female terminals 25A, 25B crimped to the ends of the electric wires W1, W2, respectively, are inserted into a pair of the terminal accommodation chambers 20, 21, which are respectively surrounded by a peripheral wall of the housing 11 and the partitioning walls 13, 14, from the terminal fitting insertion opening 11a. The locking claws 15a, 16a of the lances 15, 16 are locked to locking portions 25A-1, 25B-1, which are respectively formed on the female terminals 25A, 25B. Thereby the female terminals 25A, 25B are fixedly held inside the terminal accommodation chambers 20, 21, respectively.

The dimension of the fuse accommodation space 22 disposed at the distal side of the lances 15, 16 is set so that the fuse 30 can be removably inserted thereinto. The fuse 30 is similar to that of the JP-A-2004-158256. More specifically, the fuse 30 is approximately rectangular and has a small height (so-called low fuse). An input terminal 32 and an output terminal 33 parallel therewith are exposed from cut-outs 31a, 31b disposed at left and right sides of the fuse body 31 made of resin. A stepped portion 22a to which an upper end surface of the fuse body 31 is locked may be formed on an inner surface of the upper end of the fuse accommodation space 22.

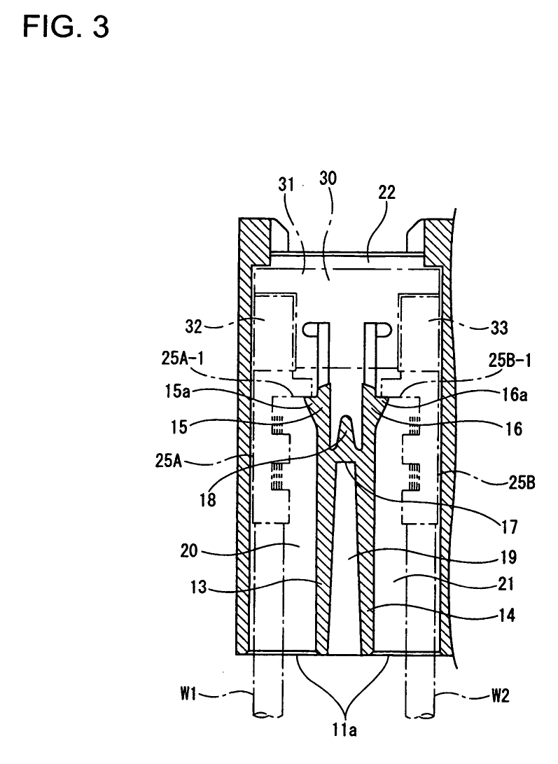

In the fuse connection box 10, as shown in FIG. 3, the female terminals 25A, 25B are inserted into the terminal accommodation chambers 20, 21, respectively and locked to the lances 15, 16, respectively. When the fuse 30 is inserted into the fuse accommodation space 22 from the fuse insertion opening 11b in this state, the female terminals 25A and 25B crimped to the ends of the electric wires W1, W2, respectively, are contacted with the input terminal 32 and the output terminal 33, respectively, of the fuse 30. Thereby the fuse 30 and the electric wires are electrically connected with each other.

When it is necessary to remove the female terminals 25A, 25B from the fuse connection box 10, the fuse 30 is pulled out of the fuse insertion opening 11b.

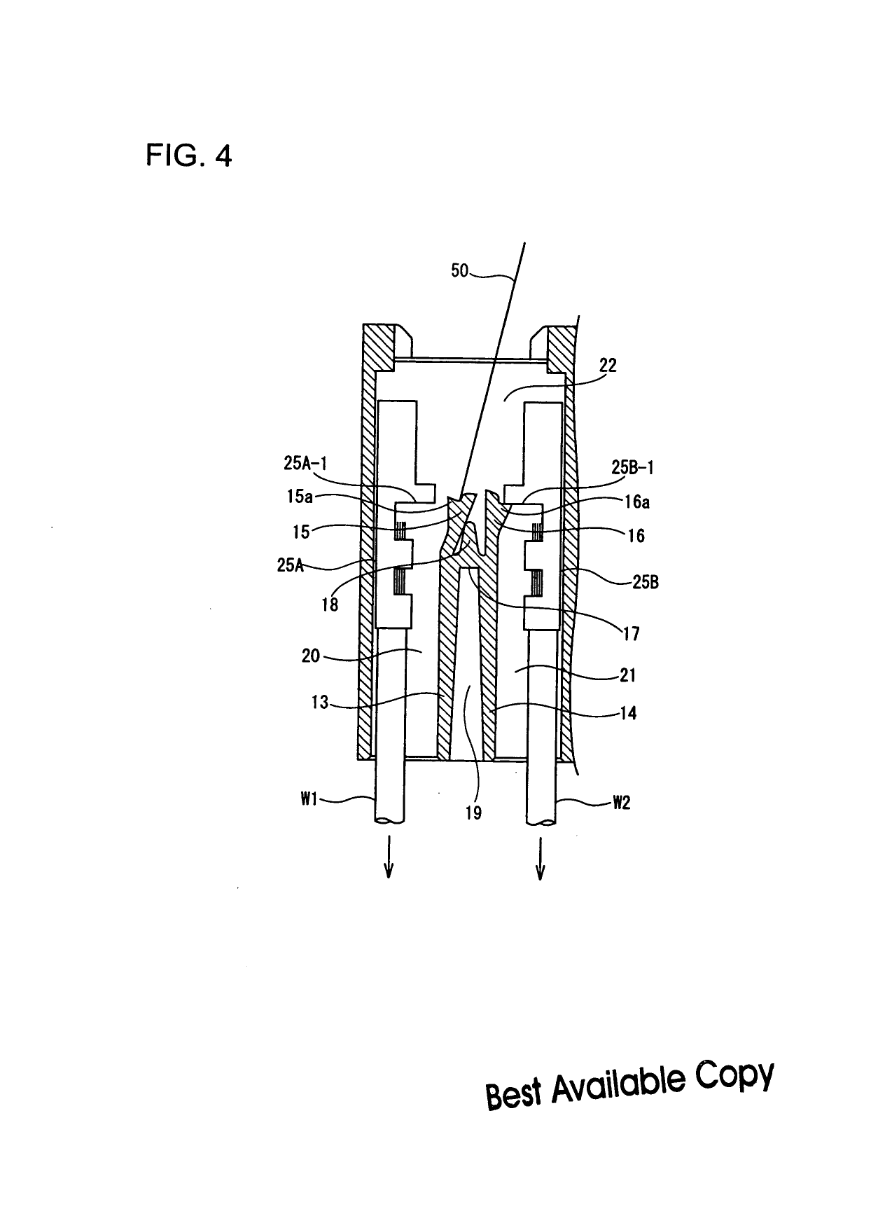

Thereafter, as shown in FIG. 4, a rod-shaped unlocking jig 50 is inserted into the fuse accommodation space 22 from the fuse insertion opening 11b to pull out the terminal 25A from the terminal fitting insertion opening 11a by unlocking the locking portion 25A-1 of the terminal 25A and the lance 15 from each other. Similarly the unlocking jig 50 is inserted into the fuse accommodation space 22 from the fuse insertion opening 11b to pull out the terminal 25B from the terminal fitting insertion opening 11a by unlocking the locking portion 25B-1 of the terminal 25B and the lance 16 from each other.

In unlocking the locking portions of the terminals and the lances from each other with the unlocking jig 50, the lances 15, 16 are elastically deformed toward a side opposite to the locking side. When the lance 15 is elastically deformed and contacts one inclined surface 18a of the flexing restraining rib 18, the lance 15 is prevented from elastically deforming beyond the contact position. Thus it is possible to prevent the lance 15 from excessively elastically deforming.

Similarly, when the lance 16 is elastically deformed and contacts the other inclined surface 18b of the flexing restraining rib 18, the lance 16 is prevented from elastically deforming beyond the contact position. Thus it is possible to prevent the lance 16 from excessively elastically deforming.

The flexing restraining rib 18 is preferably mountain-shaped, to allow the elastically deformed lances 15, 16 to make a surface contact with the inclined surfaces 18a, 18b respectively. Therefore a stress caused by the elastic deformation does not concentrate on any one point of each of the lances 15, 16. Therefore, the lances 15, 16 may be prevented from being damaged or broken.

The partitioning walls 13, 14 having the lances 15, 16 respectively formed at the upper ends thereof may be connected to each other with the reinforcing connection frame 17 at the proximal portions of the lances 15, 16. Thus, the partitioning walls 13, 14 are prevented from elastically deforming. Therefore, when the terminals 25A, 25B are taken out of the fuse connection box 10 with the unlocking jig 50, it is possible to prevent the lances 15, 16 from being damaged and the partitioning walls 13, 14 from being deformed and/or damaged.

In the fuse connection box 10 of an embodiment of the present invention, although an opening is formed at the lower end of the space between the partitioning walls 13, 14, the reinforcing connection frame 17 connecting the partitioning walls 13, 14 to each other is provided in the space between the partitioning walls 13, 14. Thus the reinforcing connection frame 17 serves as a waterproof wall. Therefore it is possible to reliably prevent water which has penetrated into the fuse connection box 10 from the opening from entering the portion of the fuse connection box where there is contact between the terminal of the fuse 30 and the female terminals 25A, 25B.

Further, in the exemplary embodiments of the invention, because the height of the fuse to be connected with the terminals is smaller than the height of a fuse where the terminals extend from the fuse body, the fuse connection box 10 may be more compact and lightweight. Therefore, the fuse connection box 10 may be able to be manufactured at a reduced cost.

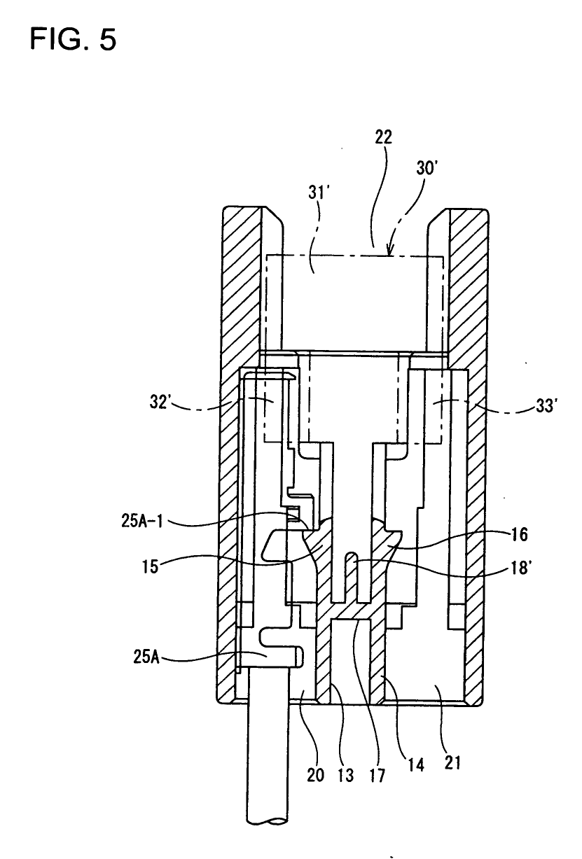

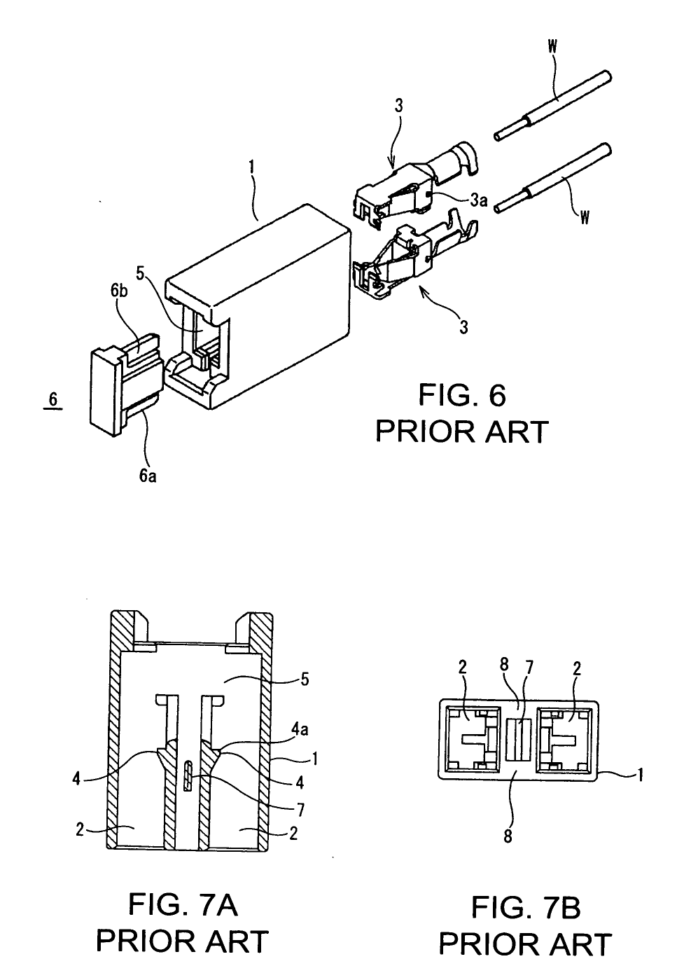

FIG. 5 shows a second embodiment. In the second embodiment, a mini-fuse 30′, different from the first embodiment, is mounted inside the fuse connection box. In the second embodiment, the lances 15, 16 formed at the upper ends of the partitioning walls 13, 14, respectively, are disposed nearer to the fuse insertion opening 11b than the lances 15, 16 of the first embodiment. Portions of the partitioning walls 13 and 14 in the vicinity of the proximal portions of the lances 15, 16 are connected to each other with the reinforcing connection frame 17. A rod-shaped flexing restraining rib 18′ is projected upward from a central portion of the reinforcing connection frame 17, with a gap formed between the flexing restraining rib 18′ and the lances 15, 16 disposed at both sides thereof.

Similarly to the first embodiment, in the second embodiment, in taking out the female terminals 25A, 25B from the fuse connection box by unlocking the female terminals 25A, 25B from the lances 15, 16, respectively, the unlocking jig 50 is inserted into the locking portions of the female terminals 25A, 25B to elastically deform the lances 15, 16. Thereby the female terminals 25A, 25B are unlocked from the lances 15, 16, respectively.

When the lances 15, 16 flex excessively, they contact the rod-shaped flexing restraining rib 18′. Therefore, it is possible to prevent the lances 15, 16 from flexing excessively and thereby reduce the possibility of breaking them.

Similarly to the first embodiment, in the second embodiment, the reinforcing connection frame 17 may function as a waterproof wall and enhance the waterproof performance of the fuse connection box.

Although the invention has been described with reference to specific embodiments, those embodiments should be viewed as illustrative and not limiting. Various modifications, substitutions and improvements are possible within the spirit and scope of the invention.

What is claimed is:

1. A fuse connection box with a housing that includes a terminal accommodation space accessible from a terminal insertion opening disposed at a first end of the housing to accommodate a pair of terminal fittings; and a fuse accommodation space accessible from a fuse insertion opening disposed at a second end of the housing to accommodate a fuse and to connect input and output terminals of said fuse with a pair of said terminal fittings wherein said housing of said fuse connection box comprises:
a pair of partitioning walls extending from said terminal insertion opening inside said terminal accommodation space, with said partitioning walls spaced from each other at a certain interval;
a pair of terminal accommodation chambers surrounded by said partitioning walls and a peripheral wall of said housing;
a pair of lances, to be locked to locking portions of said terminal fittings which is provided at distal ends of a pair of said partitioning walls;
a reinforcing connection frame connecting a pair of said partitioning walls to each other; and
a flexing restraining rib projecting from an upper surface of said reinforcing connection frame.

2. A fuse connection box according to claim 1, wherein said reinforcing connection frame connecting a pair of said partitioning walls to each other serves as a waterproof wall.

3. A fuse connection box according to claim 1, wherein
said reinforcing connection frame is disposed in the vicinity of proximal positions of a pair of said lances; and
the flexing restraining rib is sectionally mountain-shaped and projects from a central portion of said reinforcing connection frame, with a gap between said flexing restraining rib and said lances gradually increasing toward free ends of said lances.

4. A fuse connection box according to claim 1, wherein
said reinforcing connection frame is spaced at a certain interval from proximal positions of a pair of said lances; and
the flexing restraining rib is rod-shaped, and projects from a central portion of said reinforcing connection frame, with a gap formed between said flexing restraining rib and said lances disposed at both sides of said flexing restraining rib.

5. A fuse connection box according to claim 1, wherein said fuse to be accommodated in said fuse accommodation space comprises an input terminal and an output terminal parallel therewith both exposed from cut-outs disposed at left and right sides of a fuse body; and a height of said fuse accommodation space is so set that said fuse body can be fitted therein.

6. A fuse connection box according to claim 2, wherein
said reinforcing connection frame is disposed in the vicinity of proximal positions of a pair of said lances; and
the flexing restraining rib is sectionally mountain-shaped and projects from a central portion of said reinforcing connection frame, with a gap between said flexing restraining rib and said lances gradually increasing toward free ends of said lances.

7. A fuse connection box according to claim 2, wherein
said reinforcing connection frame is spaced at a certain interval from proximal positions of a pair of said lances; and
the flexing restraining rib is rod-shaped, and projects from a central portion of said reinforcing connection frame, with a gap formed between said flexing restraining rib and said lances disposed at both sides of said flexing restraining rib.

8. A fuse connection box according to claim 2, wherein said fuse to be accommodated in said fuse accommodation space comprises an input terminal and an output terminal parallel therewith both exposed from cut-outs disposed at left and right sides of a fuse body; and a height of said fuse accommodation space is so set that said fuse body can be fitted therein.

9. A fuse connection box according to claim 3, wherein
said fuse to be accommodated in said fuse accommodation space comprises an input terminal and an output terminal parallel therewith both exposed from cut-outs disposed at left and right sides of a fuse body; and a height of said fuse accommodation space is so set that said fuse body can be fitted therein.

10. A fuse connection box according to claim 4, wherein
said fuse to be accommodated in said fuse accommodation space comprises an input terminal and an output terminal parallel therewith both exposed from cut-outs disposed at left and right sides of a fuse body; and a height of said fuse accommodation space is so set that said fuse body can be fitted therein.

11. A fuse connection box according to claim 6, wherein said fuse to be accommodated in said fuse accommodation space comprises an input terminal and an output terminal parallel therewith both exposed from cut-outs disposed at left and right sides of a fuse body; and a height of said fuse accommodation space is so set that said fuse body can be fitted therein.

12. A fuse connection box according to claim 7, wherein said fuse to be accommodated in said fuse accommodation space comprises an input terminal and an output terminal parallel therewith both exposed from cut-outs disposed at left and right sides of a fuse body; and a height of said fuse accommodation space is so set that said fuse body can be fitted therein.
